(19) United States
(12) Patent Application Publication
(10) Pub. No.: US 2014/0184307 A1
(43) Pub. Date: Jul. 3, 2014

(54) GATE DRIVER HAVING FUNCTION OF PREVENTING SHOOT-THROUGH CURRENT

(71) Applicant: Samsung Electro-Mechanics Co., Ltd., Gyeonggi-do (KR)

(72) Inventors: Jong Tae Hwang, Gyeonggi-do (KR); Yun Joong Lee, Gyeonggi-do (KR); Je Hyeon Yu, Gyeonggi-do (KR); Deuk Hee Park, Gyeonggi-do (KR); Sang Hyun Cha, Gyeonggi-do (KR)

(73) Assignee: SAMSUNG ELECTRO-MECHANICS CO., LTD., Gyeonggi-do (KR)

(21) Appl. No.: 13/957,390

(22) Filed: Aug. 1, 2013

(30) Foreign Application Priority Data
Dec. 27, 2012 (KR) 10-2012-0155032

(51) Int. Cl. H03K 17/16

(52) U.S. Cl. CPC H03K 17/161
USPC 327/384

(57) ABSTRACT

Disclosed herein is a gate driver having a function of preventing shoot-through current. The gate driver having a function of preventing shoot-through current includes: a first power switch sourcing current according to voltage applied by a voltage source; a second power switch connected with the first power switch in series and sinking current according to voltage applied by the voltage source; and a shoot-through current preventing circuit preventing the occurrence of shoot-through current in first and second power switches at the time of driving of the first and second power switches. According to the present invention, the shoot-through current preventing circuit configured of the plurality of PMOSs and NMOSs can prevent the shoot-through current from occurring in the power transistor of the output terminal at the time of the driving of the gate driver, thereby preventing the unnecessary power consumption and the occurrence of ground noise.

### CROSS REFERENCE(S) TO RELATED APPLICATIONS

This application claims the benefit under 35 U.S.C. Section 119 of Korean Patent Application Serial No. 10-2012-0155032 entitled “Gate Driver Having Function Of Preventing Shoot-Through Current” filed on Dec. 27, 2012, which is hereby incorporated by reference in its entirety into this application.

### BACKGROUND OF THE INVENTION

1. Technical Field

The present invention relates to a gate driver used in a power IC, and the like, and more particularly, to a gate driver having a function of preventing shoot-through current from occurring in a power transistor of an output terminal at the time of driving of the gate driver.

2. Description of the Related Art

FIG. 1 is a diagram illustrating an example of a driver configured of a PMOS and an NMOS according to the related art.

As illustrated in FIG. 1, when there is a driver configured of a first power switch MP (PMOS) and a second power switch MN (NMOS), it is assumed that an input pulse IN is applied as illustrated in FIG. 2. As illustrated in FIG. 2, a period in which both of the first power switch MP and the second power switch MN are operated during a transient period of an input is present, such that shoot-through current Ish passing through the first power switch MP and the second power switch MN occurs as illustrated in FIG. 1.

In case of the gate driver, a size of the first power switch MP and the second power switch MN is generally large and the shoot-through current Ish is very large accordingly. Therefore, unnecessary power consumption occurs and a large mount of current flows through a ground, which causes pulse type ground noise. Therefore, there is a need to prevent the shoot-through current from occurring.

FIG. 3 is a diagram illustrating an example of a shoot-through current preventing circuit.

Referring to FIG. 3, the shoot-through current preventing circuit according to the related art is configured to include a delay circuit 310 that delays and outputs the input pulse IN from the outside by a predetermined time, an OR gate 320 that receives an output pulse IND and the input pulse IN of the delay circuit 310 to perform an OR operation and provides an output signal PDRV as a gate driving signal of the first power switch MP (PMOS), and an AND gate 330 that receives the output pulse IND and the input pulse IN of the delay circuit 310 to perform an AND operation and provides an output signal NDRV as a gate driving signal of the second power switch MN (NMOS).

As illustrated in FIG. 4, the shoot-through current preventing circuit according to the related art configured as described above uses the input pulse IN and the pulse IND obtained by delaying the input pulse IN by a predetermined time to generate signals NDRV and PDRV driving the second power switch MN and the first power switch MP, respectively.

That is, after the second power switch MN is turned off and delayed by the predetermined time, the PDRV driving the first power switch MP is generated, such that the shoot-through current may be removed. However, since the delay is adjusted according to the size of the second power switch MN and the first power switch MP, there is a problem in that the delay needs to be adjusted for implementing the optimal operation state.

### RELATED ART DOCUMENT

### Patent Document

(Patent Document 1) US Patent Laid-Open Publication No. US 2012-0176162

(Patent Document 2) JP Patent Laid-Open Publication No. 2008-199607

### SUMMARY OF THE INVENTION

An object of the present invention is to provide a gate driver having a function of preventing shoot-through current capable of preventing unnecessary power consumption and the occurrence of ground noise by preventing the shoot-through current from occurring in a power transistor of an output terminal at the time of driving of the gate driver.

According to an exemplary embodiment of the present invention, there is provided a gate driver having a function of preventing shoot-through current, including: a first power switch sourcing current according to voltage applied by a voltage source; a second power switch connected with the first power switch in series and sinking current according to voltage applied by the voltage source; and a shoot-through current preventing circuit preventing the occurrence of shoot-through current in first and second power switches at the time of driving of the first and second power switches.

The gate driver having a function of preventing shoot-through current may further include: first and second inverter units each installed at gate driving signal input terminals of the first and second power switches and each inverting and outputting a level of an input signal in connection with a turn on/off of the first and second power switches.

The gate driver having a function of preventing shoot-through current may further include: a level shifter shifting a level from low voltage of an input terminal to high voltage so as to drive the first power switch.

The shoot-through current preventing circuit may be configured of a serial-parallel combination circuit of a plurality of P channel type MOSFETs and N channel type MOSFETs.

The shoot-through current preventing circuit may be configured of a serial-parallel combination circuit of the two PMOSs and NMOSs, respectively.

The shoot-through current preventing circuit may be configured of two pairs of unit circuits disposed so that the PMOS and the NMOS form a diagonal to each other one by one and may be configured so that a drain of the PMOS and a drain of the NMOS of the respective unit circuit are each connected with each other, a source of a PMOS M6 adjacently disposed to output terminals out of the gate drivers among the PMOSs and the NMOSs of the respective unit circuit is connected with a gate of the first power switch, a source of an NMOS M5 is connected with a gate of the second power switch, a gate of the PMOS M6 is connected with a negative (−) terminal of a second voltage source VDD2, and a gate of the NMOS M5 is connected with a positive (+) terminal of a first voltage source VDD1.

A PMOS M22 may be further installed between the gate of the NMOS M5 adjacently disposed to the output terminal out of the gate driver and a source of an NMOS M2 adjacently disposed to a pulse input terminal IN from the outside among the NMOSs of the respective unit circuit so as to prevent an uncertain operation of a second inverter INV2 of a first inverter unit.

A source of the PMOS M22 may be connected with the gate of the NMOS M5, a drain of the PMOS M22 may be connected with a common node between the source of the NMOS M2 and an input terminal of the second inverter INV2, and a gate of the PMOS M22 may be connected with an output terminal of the second inverter INV2.

An NMOS M44 may be further installed between the gate of the PMOS M6 adjacently disposed to the output terminal out of the gate driver and a source of a PMOS M4 adjacently disposed to a pulse input terminal IN from the outside among the PMOSs of the respective unit circuit so as to prevent an uncertain operation of a fifth inverter INV5 of a second inverter unit.

A source of the NMOS M44 may be connected with the gate of the PMOS M6, a drain of the NMOS M44 may be connected with a common node between the source of the PMOS M4 and an input terminal of the fifth inverter INV5, and a gate of the NMOS M44 may be connected with an output terminal of the fifth inverter INV5.

### BRIEF DESCRIPTION OF THE DRAWINGS

FIG. 1 is a diagram illustrating an example of a driver configured of a PMOS and an NMOS according to the related art.

FIG. 2 is a diagram schematically illustrating the generation of shoot-through current passing through first and second power switches when an input pulse is applied to the driver of FIG. 1.

FIG. 3 is a diagram illustrating an example of a shoot-through current preventing circuit according to the related art.

FIG. 4 is a diagram illustrating output pulses of a delay circuit, an OR gate and an AND gate to an input pulse of an input terminal of the shoot-through current preventing circuit of FIG. 3.

FIG. 5 is a diagram illustrating a structure of a gate driver having a function of preventing shoot-through current according to an embodiment of the present invention.

FIG. 6 is a diagram illustrating an operation of the gate driver having the function of preventing shoot-through current according to the embodiment of the present invention.

FIG. 7 is a diagram illustrating a structure of a gate driver having a function of preventing shoot-through current according to another embodiment of the present invention.

FIG. 8 is a diagram illustrating a simulation result that the first and second power switches of the gate driver having the function of preventing shoot-through current according to the exemplary embodiment of the present invention are not turned on simultaneously.

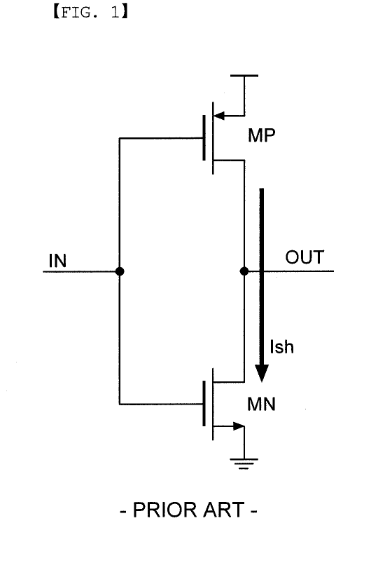

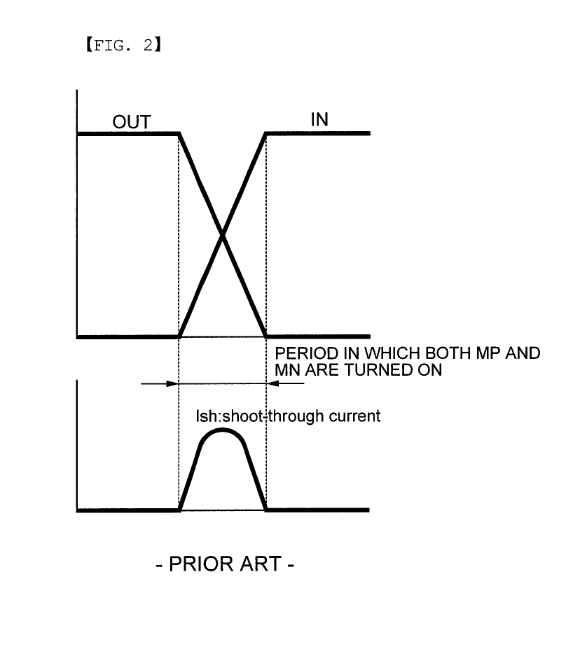

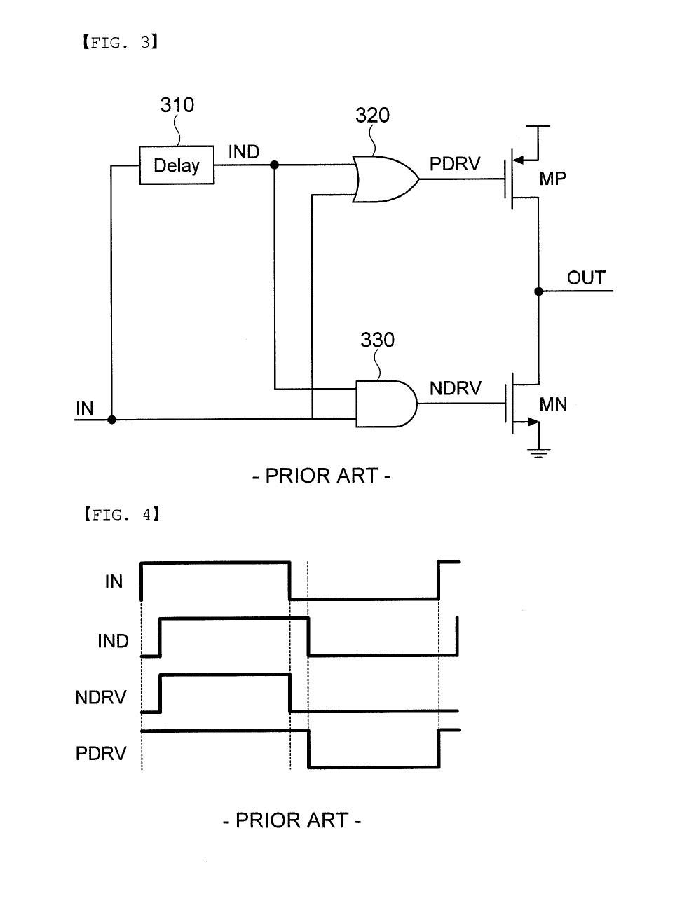

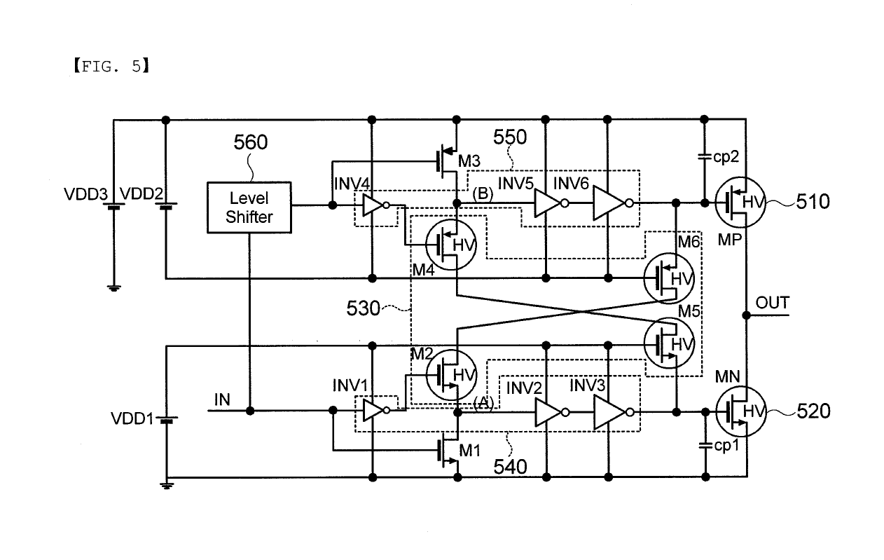

### DESCRIPTION OF THE PREFERRED EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Throughout the specification, unless explicitly described otherwise, “comprising” any components will be understood to imply the inclusion of other components but not the exclusion of any other components. In addition, a term “part”, “module”, “unit”, or the like, described in the specification means a unit of processing at least one function or operation and may be implemented by hardware or software or a combination of hardware and software.

Hereinafter, exemplary embodiments of the present invention will be described in detail with reference to the accompanying drawings.

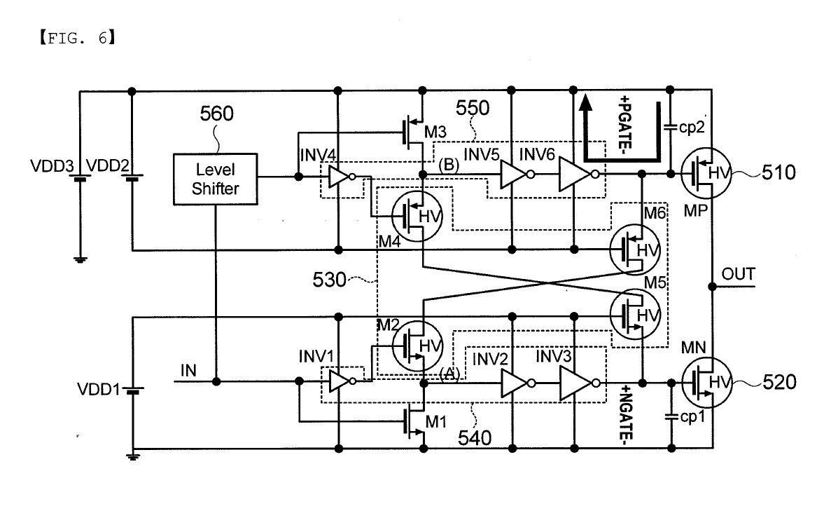

FIG. 5 is a diagram illustrating a structure of a gate driver having a function of preventing shoot-through current according to an embodiment of the present invention.

Referring to FIG. 5, the gate driver having the function of preventing shoot-through current according to the exemplary embodiment of the present invention is configured to include a first power switch 510, a second power switch 520, and a shoot-through current preventing circuit 530.

The first power switch 510 serves to source current according to voltage applied by a voltage source. The first power switch 510 may be configured of PMOS.

The second power switch 520 is connected with the first power switch 510 in series and serves to sink current according to voltage applied by the voltage source. The second power switch 520 may be configured of NMOS.

The shoot-through current preventing circuit 530 serves to prevent the generation of shoot-through current in the first and second power switches 510 and 520 at the time of the driving of the first and second power switches 510 and 520.

Herein, preferably, the shoot-through current preventing circuit 530 further includes first and second inverter units 540 and 550 that are installed at the gate driving signal input terminals of the first and second power switches 510 and 520, respectively, and inverts and outputs levels of input signals, respectively, in connection with the turn on/off of the first and second power switches 510 and 520.

Further, the shoot-through current preventing circuit 530 may further include a level shifter 560 that shifts low voltage of the input terminal into high voltage so as to drive the first power switch 510.

Further, the shoot-through current preventing circuit 530 may be configured of a serial-parallel combination circuit of a plurality of P channel type MOSFETs and N channel type MOSFETS.

In this case, the shoot-through current preventing circuit 530 may be configured of a serial-parallel combination circuit of two PMOSs M4 and M6 and NMOSs M2 and M5, respectively.

In this case, the shoot-through current preventing circuit 530 is configured of two pairs of unit circuits disposed so that the PMOS and NMOS (that is, M6 and M2 and M4 and M5) form a diagonal to each other one by one and is configured so that a drain of the PMOS and a drain of the NMOS (that is, M6 and M2 and M4 and M5) of the respective unit circuit are each connected with each other, a source of the PMOS M6 adjacently disposed to output terminals out of the gate drivers among the PMOSs and the NMOSs of the respective unit circuit is connected with a gate of the first power switch 510, a source of the NMOS M5 is connected with a gate of the second power switch 520, a gate of the PMOS M6 is connected with a negative (−) terminal of a second voltage source VDD2, and a gate of the NMOS M5 is connected with a positive (+) terminal of a first voltage source VDD1.

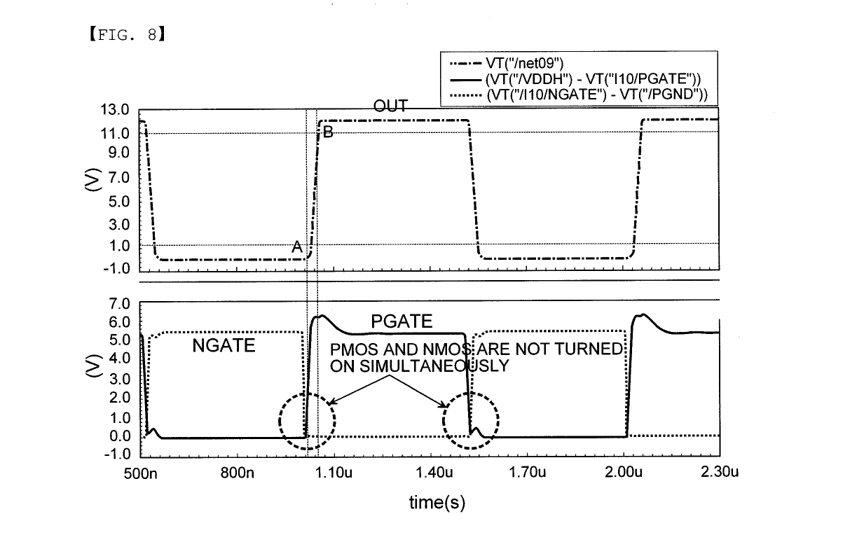

In this case, preferably, as illustrated in FIG. 7, a PMOS M22 may be further installed between the gate of the NMOS M5 adjacently disposed to the output terminal out of the gate driver and a source of an NMOS M2 adjacently disposed to a pulse input terminal IN from the outside among the NMOSs of the respective unit circuit so as to prevent an uncertain operation of a second inverter INV2 of the first inverter unit 540.

In this case, a source of the PMOS M22 is connected with the gate of the NMOS M5, a drain of the PMOS M22 is connected with a common node A between the source of the NMOS M2 and an input terminal of the second inverter INV2, and a gate of the PMOS M22 is connected with an output terminal of the second inverter INV2.

In this case, preferably, as illustrated in FIG. 7, an NMOS M44 may be further installed between a gate of the PMOS M6 adjacently disposed to the output terminal out of the gate driver and a source of the PMOS M4 adjacently disposed to the pulse input terminal IN from the outside among the PMOSs of the respective unit circuit so as to prevent an uncertain operation of a fifth inverter unit 550 of the second inverter unit 550.

In this case, a source of the NMOS M44 is connected with the gate of the PMOS M6, a drain of the NMOS M44 is connected with a common node A between the source of the PMOS M4 and the input terminal of the fifth inverter INV5, and a gate of the NMOS M44 is connected with the output terminal of the fifth inverter INV5.

Generally, when an oxide of the gate is not thick, a withstand voltage of a gate-source of MOSFET is smaller than that of a drain-source of the MOSFET.

Therefore, a circuit of the gate driver having the function of preventing shoot-through current according to the exemplary embodiment of the present invention configured as described above is configured to be able to limit the gate voltage of the first power switch 510 and the second power switch 520, respectively, to VDD2 and VDD1.

In connection with this, the withstand voltage characteristics of the gate driver according to the exemplary embodiment of the present invention is as follows.

1) The withstand voltage of the gate-source of all the used elements is smaller than VDD3.

2) In case of HV MOSFET, the withstand voltage of the drain-source is larger than VDD3.

3) MOSFETs other than the HV MOSFET, the withstand voltage of the drain-source is smaller than VDD3.

In this circuit structure, a level shifter circuit that transfers the low-voltage input power (IN) signal as high voltage so as to drive the first power switch 510. Therefore, in the exemplary embodiment of the present invention, as described above, the gate driver is configured to further include the level shifter 560.

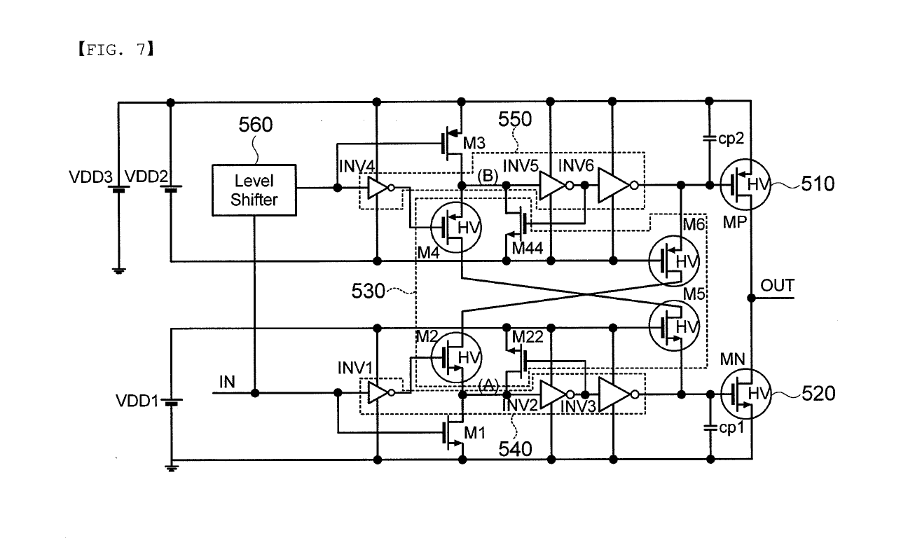

Next, an operation of the gate driver having the function of preventing shoot-through current according to the exemplary embodiment of the present invention will be described with reference to FIG. 6.

Referring to FIG. 6, for example, when the input power IN is high H, the first power switch 510 is in a turned on state and thus PGATE voltage becomes VDD2.

In this state, when the input power IN is changed to low L, the second power switch 520 needs to be turned-on. However, it takes time to discharge voltage of cp2 that is a parasitic capacitor by the sixth inverter INV6 of the second inverter unit 550, such that the first power switch 510 is still in the turned-on state.

In this state, when the second power switch 520 is turned on, the shoot-through current occurs. However, in the state in which the PGATE voltage is similar to the VDD2, the gate-source voltage of the PMOS M6 at the output terminal ‘out’ side of the shoot-through current preventing circuit 530 is substantially 0, such that current does not flow.

Therefore, since there is no current supplied to the NMOS M2 at the input terminal side of the shoot-through current preventing circuit 530, a potential of (A) node may not be increased even when the M2 is turned on. Therefore, the second power switch 520 is not turned on.

As time lapses, the voltage of the cp2 that is a parasitic capacitor is discharged to be reduced, such that the voltage of the cp2 is zero and the M6 is in the turned on state. Further, since current is supplied to the M2 by the M6, the (A) node voltage is increased for the first time and the second power switch 520 may be turned on.

In the above operation, the second power switch 520 is not turned on until the first power switch 510 is turned off, and therefore the shoot-through current is not generated.

Meanwhile, during a series of operation processes as described above, when the NMOS M2 at the input terminal side of the shoot-through current preventing circuit 530 is turned on, there is a problem in that the potential of the (A) node may be limited to VDD1-Vth2 (threshold voltage of M2). Therefore, when the INV2 cannot be certainly turned on, in some cases, both of the NMOS and PMOS configuring the INV2 are operated, such that the power consumption may occur. Therefore, according to the exemplary embodiment of the present invention, as described in FIG. 7, the shoot-through current preventing circuit 530 is separately added with the PMOS M22 and the NMOS M44.

Describing in more this with reference to FIG. 7, current drivability of the M22 is smaller than that of Ml and M2 and similarly, current drivability of the M44 is very smaller than that of M3 and M4.

Therefore, M22 and M44 alone may not determine the (A) and (B) node voltage. However, as described above, when the M2 is turned on, the output of the second inverter INV2 is low L, and thus the M22 is turned on, such that the (A) node certainly becomes VDD1, thereby preventing the uncertain operation of the second inverter INV2.

Meanwhile, FIG. 8 is a diagram illustrating a simulation result that the first and second power switches of the gate driver having the function of preventing shoot-through current according to the exemplary embodiment of the present invention are not turned on simultaneously.

It can be appreciated from FIG. 8 that the NGATE and the PGATE are not high simultaneously, and thus the second power switch 520 and the first power switch 510 are not turned on simultaneously. The foregoing simulation method is automatically performed even when the size of the second power switch 520 and the first power switch 510 is changed, such that a process of optimizing the delay as in the gate driver according to the related art is not required.

As described above, the gate driver having the function of preventing shoot-through current includes the shoot-through current preventing circuit configured of the plurality of PMOSs and NMOSs to prevent the generation of shoot-through current in the power transistor of the output terminal at the time of the driving of the gate driver, thereby preventing the unnecessary power consumption and the occurrence of ground noise.

As described above, the present invention will be described with reference to the exemplary embodiments, but is not limited thereto. It can be apparent to those skilled in the art that the exemplary embodiments of present invention can be variously changed and applied within the scope of the present invention without departing from the technical idea of the present invention. Therefore, the protection scope of the present invention must be construed by the appended claims and it should be construed that all spirits within a scope equivalent thereto are included in the appended claims of the present invention.

What is claimed is:

1. A gate driver having a function of preventing shoot-through current, comprising:
a first power switch sourcing current according to voltage applied by a voltage source;
a second power switch connected with the first power switch in series and sinking current according to voltage applied by the voltage source; and
a shoot-through current preventing circuit preventing the occurrence of shoot-through current in first and second power switches at the time of driving of the first and second power switches.

2. The gate driver having a function of preventing shoot-through current according to claim 1, further comprising:
first and second inverter units each installed at gate driving signal input terminals of the first and second power switches and each inverting and outputting a level of an input signal in connection with a turn on/off of the first and second power switches.

3. The gate driver having a function of preventing shoot-through current according to claim 1, further comprising:
a level shifter shifting a level from low voltage of an input terminal to high voltage so as to drive the first power switch.

4. The gate driver having a function of preventing shoot-through current according to claim 1, wherein the shoot-through current preventing circuit is configured of a serial-parallel combination circuit of a plurality of P channel type MOSFETs and N channel type MOSFETs.

5. The gate driver having a function of preventing shoot-through current according to claim 4, wherein the shoot-through current preventing circuit is configured of a serial-parallel combination circuit of the two PMOSs and NMOSs, respectively.

6. The gate driver having a function of preventing shoot-through current according to claim 5, wherein the shoot-through current preventing circuit is configured of two pairs of unit circuits disposed so that the PMOS and the NMOS form a diagonal to each other one by one and is configured so that a drain of the PMOS and a drain of the NMOS of the respective unit circuit are each connected with each other, a source of a PMOS M6 adjacently disposed to output terminals out of the gate drivers among the PMOSs and the NMOSs of the respective unit circuit is connected with a gate of the first power switch, a source of an NMOS M5 is connected with a gate of the second power switch, a gate of the PMOS M6 is connected with a negative (−) terminal of a second voltage source VDD2, and a gate of the NMOS M5 is connected with a positive (+) terminal of a first voltage source VDD1.

7. The gate driver having a function of preventing shoot-through current according to claim 6, wherein a PMOS M22 is further installed between the gate of the NMOS M5 adjacently disposed to the output terminal out of the gate driver and a source of an NMOS M2 adjacently disposed to a pulse input terminal IN from the outside among the NMOSs of the respective unit circuit so as to prevent an uncertain operation of a second inverter INV2 of a first inverter unit.

8. The gate driver having a function of preventing shoot-through current according to claim 7, wherein a source of the PMOS M22 is connected with the gate of the NMOS M5, a drain of the PMOS M22 is connected with a common node between the source of the NMOS M2 and an input terminal of the second inverter INV2, and a gate of the PMOS M22 is connected with an output terminal of the second inverter INV2.

9. The gate driver having a function of preventing shoot-through current according to claim 6, wherein an NMOS M44 is further installed between the gate of the PMOS M6 adjacently disposed to the output terminal out of the gate driver and a source of a PMOS M4 adjacently disposed to a pulse input terminal IN from the outside among the PMOSs of the respective unit circuit so as to prevent an uncertain operation of a fifth inverter INV5 of a second inverter unit.

10. The gate driver having a function of preventing shoot-through current according to claim 9, wherein a source of the NMOS M44 is connected with the gate of the PMOS M6, a drain of the NMOS M44 is connected with a common node between the source of the PMOS M4 and an input terminal of the fifth inverter INV5, and a gate of the NMOS M44 is connected with an output terminal of the fifth inverter INV5.
